(19) United States
(12) Patent Application Publication
(10) Pub. No.: US 2023/0133983 A1
(43) Pub. Date: May 4, 2023

(54) ORGANIC LIGHT-EMITTING DISPLAY DEVICE

(71) Applicant: LG DISPLAY CO., LTD., Seoul (KR)

(72) Inventors: Daehee KIM, Goyang-si (KR); Hyunmin PARK, Goyang-si (KR)

(73) Assignee: LG DISPLAY CO., LTD., SEOUL (KR)

(21) Appl. No.: 17/947,303

(22) Filed: Sep. 19, 2022

(30) Foreign Application Priority Data
Oct. 28, 2021 (KR) 10-2021-0145931

(51) Int. Cl. H01L 51/52; H01L 27/32

(52) U.S. Cl. CPC H01L 51/5253; H01L 27/3293

(57) ABSTRACT

An organic light-emitting display device includes a substrate including a display area in which a plurality of pixels are disposed, and a non-display area surrounding the display area; a dam pattern surrounding the display area and positioned in the non-display area; a first barrier pattern positioned in a first barrier area between the dam pattern and the display area; a second barrier pattern positioned in a second barrier area outside the dam pattern; an organic light-emitting element layer positioned in a pixel area, the first barrier area, and the second barrier area, wherein the organic light-emitting element layer is divided into discontinuous portions spaced from each other via each of the first barrier pattern and the second barrier pattern; and an encapsulation portion covering the display area, the organic light-emitting element layer, the first barrier pattern and the second barrier pattern.

### CROSS-REFERENCE TO RELATED APPLICATION

This application claims the priority of Korean Patent Application No. 10-2021-0145931 filed on Oct. 28, 2021, which is hereby incorporated by reference in its entirety.

### BACKGROUND

### Field of the Disclosure

The present disclosure relates to an organic light-emitting display device, and more particularly, to an organic light-emitting display device in which an invasion path of moisture and oxygen to an organic light-emitting element is blocked to improve reliability of the organic light-emitting element.

### Description of the Background

Display devices are applied to various electronic devices such as TVs, mobile phones, laptops, and tablets. Further, recently, demand for a large-screen display device that implements a large-area screen by arranging a plurality of display devices in a grid manner is increasing. Accordingly, research to develop thin, lightweight, and low power consuming display device is continuing.

An organic light-emitting display device (OLED) includes a display area where an image is displayed and a non-display area surrounding the display area. A plurality of pixel areas are arranged in the display area of the organic light-emitting display device. A plurality of organic light-emitting elements corresponding to the plurality of pixel areas are included in the device. The organic light-emitting element is self-emissive. Thus, the organic light-emitting display device has advantages of faster response speed, greater luminous efficiency, luminance and viewing angle, and excellent contrast ratio and color gamut, compared to a liquid crystal display device.

The organic light-emitting element include an organic material that may be easily degraded by moisture and oxygen. Accordingly, research on a method of blocking a travel path of moisture and oxygen to prevent the organic material from being exposed to the moisture and oxygen to prevent the organic material from being deteriorated is in progress.

In particular, as the demand for the large-screen display device that implements a large-area screen by arranging a plurality of display devices in the grid manner increases, blocking the invasion path of the moisture and oxygen into the organic light-emitting element is becoming an important issue.

The organic light-emitting display device includes the display area implemented to display an image. In the non-display area surrounding the display area, circuit, a pad area, etc. are disposed. Thus, a structure, for example, a bezel to screen the circuit, the pad area, etc. from a user's view is disposed in the non-display area. However, when the large-screen display device is implemented, a seam as a bezel disposed between adjacent display devices is visible to a viewer. When a single image is displayed on the large-screen display device, the seam causes discontinuity of the image to lower the user's immersion in the image.

Therefore, research is being conducted to reduce a width of the bezel to remove the seam. However, when the width of the bezel is reduced to the extreme, moisture or oxygen invasion becomes easier such that the organic light-emitting element is deteriorated to lower reliability of the organic light-emitting display device.

### SUMMARY

Accordingly, the present disclosure is to provide an organic light-emitting display device in which a factor causing deterioration of a light-emitting element when a width of a bezel between adjacent display devices in a large-screen display device implemented by arranging a plurality of display devices in a matrix manner is reduced may be removed to maintain performance of the light-emitting element.

The present disclosure is also to provide an organic light-emitting display device in which a plurality of barrier patterns are introduced on a bezel area to block moisture invading from a side face of a substrate to prevent deterioration of performance of a light-emitting element disposed inside the display device.

Further, the present disclosure is to provide is an organic light-emitting display device in which a plurality of barrier patterns are disposed on a bezel area to make the light-emitting element discontinuous to block an invasion path of moisture to secure a lifespan of the light-emitting element to prevent the deterioration of the reliability of the display device.

The present disclosure is not limited to the above-mentioned aspects. The advantages of the present disclosure that are not mentioned may be understood based on following descriptions, and may be more clearly understood based on aspects of the present disclosure. Further, it will be easily understood that the purposes and advantages of the present disclosure may be realized using means shown in the claims and combinations thereof.

In an aspect of the present disclosure, an organic light-emitting display device includes a substrate including a display area in which a plurality of pixels are disposed, and a non-display area surrounding the display area; a dam pattern surrounding the display area and positioned in the non-display area; a first barrier pattern positioned in a first barrier area between the dam pattern and the display area; a second barrier pattern positioned in a second barrier area outside the dam pattern; an organic light-emitting element layer positioned in a pixel area, the first barrier area, and the second barrier area, wherein the organic light-emitting element layer is divided into discontinuous portions spaced from each other via each of the first barrier pattern and the second barrier pattern; and an encapsulation portion covering the display area, the organic light-emitting element layer, the first barrier pattern and the second barrier pattern.

In one implementation of the first aspect, the organic light-emitting element layer includes a first electrode, an organic light-emitting layer and a second electrode, wherein in the non-display area, each of the organic light-emitting layer and the second electrode is divided into discontinuous portions spaced from each other via each of the first barrier pattern and the second barrier pattern.

In one implementation of the first aspect, the second electrode surrounds a face of each of the discontinuous portions of the organic light-emitting layer spaced from each other via each of the first barrier pattern and the second barrier pattern.

In one implementation of the first aspect, the second barrier area is positioned between an outer side edge of the substrate and the dam pattern.

In one implementation of the first aspect, the first barrier area has a width smaller than a width of the second barrier area. In a further implementation of the first aspect, the first barrier area may have a width which is 95% or less of the width of the second barrier area. In a further implementation of the first aspect, the first barrier area may have a width which is 90% or less, 80% or less, 70% or less, 60% or less, 50% or less, 40% or less, 30% or less, 20% or less, or 10% or less of the width of the second barrier area. In a further implementation of the first aspect, the first barrier area may have a width which is 10% or more, 20% or more, 30% or more, 40% or more, 50% or more, 60% or more, 70% or more, 80% or more, or 90% or more, but less than 100% of the width of the second barrier area.

In one implementation of the first aspect, each of the first barrier pattern and the second barrier pattern includes a polymer material in which carbon-carbon bonds are continuously arranged in a chain structure so as to achieve orthogonality, wherein the polymer material contains a substantial amount of fluorine (F) at a functional group thereof.

In one implementation of the first aspect, the first barrier pattern has a frame shape surrounding four sides of the display area in a plan view of the device, wherein the second barrier pattern is positioned outside the dam pattern and has a frame shape surrounding four sides of the dam pattern in the plan view.

In one implementation of the first aspect, each of the first barrier pattern and the second barrier pattern includes a plurality of patterns.

In one implementation of the first aspect, each of the first barrier pattern and the second barrier pattern has both opposing sidewalls and a bottom portion such that a cross-sectional shape thereof is a ‘U’-shape having a valley.

In one implementation of the first aspect, a thickness of each of both opposing sidewalls and the bottom portion of each of the first barrier pattern and the second barrier pattern is in a range of 1 nm to 10 nm.

In one implementation of the first aspect, a vertical dimension (H1) of each of the both opposing sidewalls of each of the first barrier pattern and the second barrier pattern is equal to or larger than a vertical dimension (H2) of a sidewall of the second electrode surrounding the face of each of the discontinuous portions of the organic light-emitting layer. For example, a top surface of each of both opposing sidewalls of each of the first barrier pattern and the second barrier patter is equal level to a top surface of a sidewall of the second electrode. Or the top surface of each of both opposing sidewalls of each of the first barrier pattern and the second barrier patter disposed higher level than the top surface of a sidewall of the second electrode. For example, H1 can be from 100% to 200%, 101% to 150%, 102% to 140%, 103% to 130%, 104% to 120%, or 105% to 110% of H2.

In one implementation of the first aspect, the encapsulation portion includes: a first encapsulation film covering the organic light-emitting element layer, the first barrier pattern, the dam pattern, and the second barrier pattern; a cover film disposed on the first encapsulation film and covering an inner side face of the dam pattern; and a second encapsulation film positioned on the cover film, wherein the second encapsulation film covers a portion of the first encapsulation film disposed on the dam pattern and covers the second barrier pattern.

Another aspect of the present disclosure, a large-screen display device includes a plurality of organic light-emitting display devices arranged along a first direction and a second direction intersecting the first direction so as to contact each other, wherein each of the organic light-emitting display devices includes: a substrate including a display area in which a plurality of pixels are disposed, and a non-display area surrounding the display area and having a bezel area; a dam pattern surrounding the display area and positioned in the non-display area; a first barrier pattern positioned in a first barrier area between the dam pattern and the display area; a second barrier pattern positioned in a second barrier area outside the dam pattern; an organic light-emitting element layer positioned in a pixel area, the first barrier area, and the second barrier area, wherein the organic light-emitting element layer is divided into discontinuous portions spaced from each other via each of the first barrier pattern and the second barrier pattern; and an encapsulation portion covering the display area, the organic light-emitting element layer, the first barrier pattern and the second barrier pattern.

In one implementation of the second aspect, a width of a bezel area disposed between adjacent ones of the plurality of organic light-emitting display devices is smaller than a size of a pixel pitch between the adjacent ones.

In one implementation of the second aspect, the organic light-emitting element layer includes a first electrode, an organic light-emitting layer and a second electrode, wherein in the non-display area, each of the organic light-emitting layer and the second electrode is divided into discontinuous portions spaced from each other via each of the first barrier pattern and the second barrier pattern.

In one implementation of the second aspect, the second electrode surrounds a face of each of the discontinuous portions of the organic light-emitting layer spaced from each other via each of the first barrier pattern and the second barrier pattern.

In one implementation of the second aspect, each of the first barrier pattern and the second barrier pattern includes a polymer material in which carbon-carbon bonds are continuously arranged in a chain structure so as to achieve orthogonality, wherein the polymer material contains a substantial amount of fluorine (F) at a functional group thereof.

In one implementation of the second aspect, the first barrier pattern has a frame shape surrounding four sides of the display area in a plan view of the device, wherein the second barrier pattern is positioned outside the dam pattern and has a frame shape surrounding four sides of the dam pattern in the plan view.

In one implementation of the second aspect, each of the first barrier pattern and the second barrier pattern has both opposing sidewalls and a bottom portion such that a cross-sectional shape thereof is a ‘U’-shape having a valley.

In one implementation of the second aspect, a vertical dimension of each of the both opposing sidewalls of each of the first barrier pattern and the second barrier pattern is equal to or larger than a vertical dimension of a sidewall of the second electrode surrounding the face of each of the discontinuous portions of the organic light-emitting layer.

According to one aspect of the present disclosure, the plurality of barrier patterns may be provided in the bezel area to block the invasion of moisture from the side face of the substrate, thereby preventing performance of the light-emitting element disposed inside the display device to being deteriorated.

Further, according to an aspect of the present disclosure, the barrier pattern may be made of a material having the orthogonality, thereby securing the life of the organic light-emitting display device.

Further, according to an aspect of the present disclosure, the barrier pattern may be made of a fluoropolymer containing a large amount of fluorine. Thus, when the fluorine-based organic solvent is used, damage to the organic material constituting the light-emitting element may be prevented in the lift-off process.

Further, according to an aspect of the present disclosure, the thickness of the barrier pattern may be within the critical range, thereby preventing a surface of the barrier pattern from being depressed or occurrence of defects such as cracks inside the barrier pattern, thereby preventing occurrence of defects due to arcing phenomenon.

Effects of the present disclosure are not limited to the above-mentioned effects, and other effects as not mentioned will be clearly understood by those skilled in the art from following descriptions.

### BRIEF DESCRIPTION OF DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a schematic diagram to illustrate a large-screen display device;

FIG. 2 is an enlarged view of portion “I′” of FIG. 1;

FIG. 3 is a plan view schematically shown to illustrate an organic light-emitting display device according to an aspect of the present disclosure;

FIG. 4 is a cross-sectional view showing portion “II-II′” of FIG. 3;

FIG. 5 and FIG. 6 are enlarged views showing portion “X1” and portion “X2” of FIG. 4, respectively; and

FIGS. 7 to 19 are diagrams for illustrating a method for manufacturing an organic light-emitting display device according to an aspect of the present disclosure.

### DETAILED DESCRIPTIONS

Advantages and features of the present disclosure, and a method of achieving the advantages and features will become apparent with reference to aspects described later in detail together with the accompanying drawings. However, the present disclosure is not limited to aspects as disclosed below, but may be implemented in various different forms. Thus, these aspects are set forth only to make the present disclosure complete, and to completely inform the scope of the present disclosure to those of ordinary skill in the technical field to which the present disclosure belongs, and the present disclosure is only defined by the scope of the claims.

A shape, a size, a ratio, an angle, a number, etc. disclosed in the drawings for describing the aspects of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular aspects only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify an entirety of list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In one implementation of the disclosure, the expression “a substantial amount of fluorine” may mean that the number of fluorine atoms amounts up to 50% or more, or 60%, 70%, 80%, or 90% or more of the total number of the atoms of a molecule, a polymer, a material or a functional group.

In one implementation of the disclosure, the term “large-screen display device” may mean a display device having a screen of a diagonal length of 32 inches or more, 40 inches or more, 50 inches or more, 65 inches or more, 80 inches or more, 100 inches or more, 120 inches or more, 150 inches or more, 200 inches or more, or 400 inches or more.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In interpreting a numerical value, the value is interpreted as including an error range unless there is no separate explicit description thereof.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various aspects of the present disclosure may be partially or entirely combined with each other, and may be technically associated with each other or operate with each other. The aspects may be implemented independently of each other and may be implemented together in an association relationship.

In descriptions of temporal relationships, for example, temporal precedent relationships between two events such as “after”, “subsequent to”, “before”, etc., another event may occur therebetween unless “directly after”, “directly subsequent” or “directly before” is indicated.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, an organic light-emitting display device according to an aspect of the present disclosure will be described with reference to the accompanying drawings.

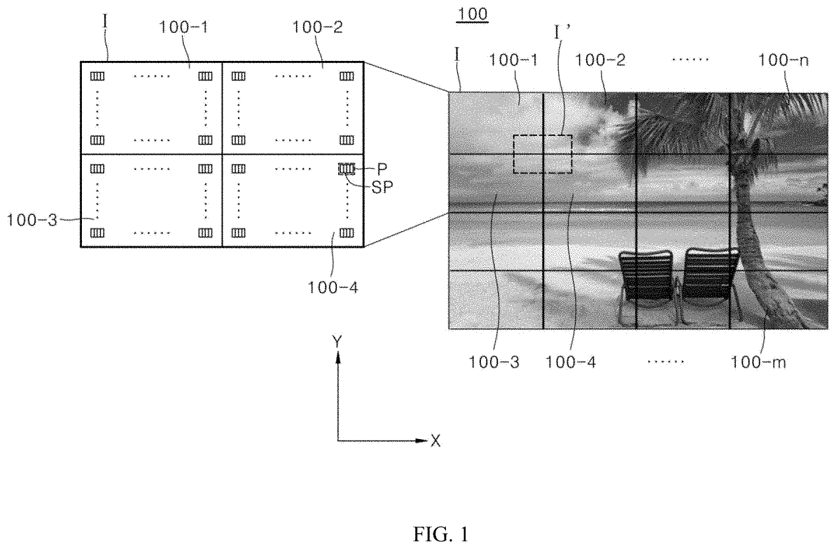

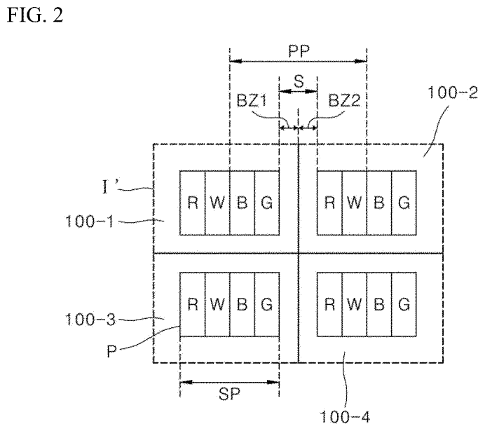

FIG. 1 is a schematic diagram to illustrate a large-screen display device. FIG. 2 is an enlarged view of a I′ portion of FIG. 1.

Referring to FIG. 1 and FIG. 2, the large-screen display device 100 is configured to include a plurality of display devices 100-1, 100-2, 100-3, 100-4 . . . 100-n, and 100-m. In this regard, each of n and m may be a natural number. The plurality of display devices 100-1, 100-2, 100-3, 100-4 . . . 100-n and 100-m may be tiled with each other along a first direction X and a second direction Y intersecting the first direction X such that adjacent display devices of the plurality of display devices 100-1, 100-2, 100-3, 100-4 . . . 100-n and 100-m contact each other. In this regard, although not shown in the drawings, a frame (not shown) may be disposed on rear faces of the plurality of display devices 100-1, 100-2, 100-3, 100-4 . . . 100-n and 100-m and may fixedly support the display devices. However, the present disclosure is not limited thereto.

Each of the plurality of display devices 100-1, 100-2, 100-3, 100-4 . . . 100-n and 100-m includes a display area including a plurality of pixels P for displaying an image. Each of the plurality of pixels P includes a plurality of sub-pixels SP. The sub-pixel SP may be the most basic color element that actually emits light, and may be understood as the smallest light-emitting unit area. In one example, as shown in FIG. 2, four sub-pixels SP adjacent to each other may include a red sub-pixel R, a white sub-pixel W, a blue sub-pixel B, and a green sub-pixel G and may constitute one pixel area P. However, the present disclosure is not limited thereto. For example, the sub-pixels SP constituting one pixel area P may be composed of three sub-pixels SP including a red sub-pixel R, a blue sub-pixel B, and a green sub-pixel G. In this regard, each of the plurality of sub-pixels SP may include an organic light-emitting element as a self-light-emitting element.

In one example, each of the plurality of display devices 100-1, 100-2, 100-3, 100-4 . . . 100-n and 100-m may have bezels BZ1 and BZ2 to block the non-display area surrounding the display area from the user's view. However, the bezels BZ1 and BZ2 disposed between adjacent ones of the display devices 100-1, 100-2, 100-3, 100-4 . . . 100-n and 100-m may be visually connected to each other and thus may be visible as a seam S as a dark area.

When one image is displayed on the large-screen display device 100, the seam S causes the image to be discontinuous, as shown in FIG. 1, thereby reducing the user's immersion in the image. In order for the user to recognize a single continuous image without the discontinuity, the seam S must be sized such that the user cannot recognize the seam S. Accordingly, one of approaches to remove the seam S that degrades the user's immersion in the image includes a scheme of reducing a width of each of the bezels BZ1 and BZ2. In one example, the width of each of the bezels BZ1 and BZ2 may be smaller than a size of a pixel pitch PP. When the width of each of the bezels BZ1 and BZ2 is smaller than the size of the pixel pitch PP, the size of the seam S as a sum of the adjacent bezels may be at least equal to or smaller than the size of the pixel pitch PP. Thus, the user recognizes a single continuous image without the discontinuity. In this way, the immersion in the image may be improved.

However, when the width of each of the bezels BZ1 and BZ2 is reduced, invasion of moisture or oxygen from a side face of the substrate may easily occur such that performance of the organic light-emitting element may be degraded.

Specifically, the organic light-emitting element may include an organic material that may be easily degraded by moisture and oxygen. That is, an overall performance of the display device, prevention of defects, and thus an overall reliability of the display device may vary depending on how much the invasion of the moisture and oxygen into the organic light-emitting element may be blocked. Thus, importance of how to block the invasion path of the moisture and oxygen into the organic light-emitting element is increasing.

The organic light-emitting element may be configured to include organic light-emitting element layers including a first electrode, an organic light-emitting layer and a second electrode. In particular, when the organic light-emitting layer is continuously formed on the display area and the non-display area, the organic light-emitting layer may act as a path through which moisture and oxygen are introduced. Accordingly, making the organic light-emitting layer discontinuous in the bezel area may allow the invasion path of moisture and oxygen from the side face of the substrate to be blocked.

A scheme of making the organic light-emitting layer discontinuous may include a process using an organic solvent, a laser ablation process using laser, or an introduction of an undercut structure to prevent moisture invasion. However, in the above-described schemes, when the width of the bezel is reduced to reduce the size of the seam, it is difficult to selectively make only a portion of the organic light-emitting layer in the bezel area discontinuous while not affecting a portion of the organic light-emitting layer in the display area. Further, as the width of the bezel decreases, a structure composed of the organic light-emitting layer may be disposed or the disposed structure may act as a foreign substance causing a defect, in the process of making the organic light-emitting layer discontinuous. Further, defects may occur due to the foreign substance induced in the process of making the organic light-emitting layer discontinuous. Further, the organic light-emitting layer may be damaged by the organic solvent in the process of making the organic light-emitting layer discontinuous.

Accordingly, an organic light-emitting display device according to an aspect of the present disclosure in which the organic light-emitting layer is prevented from being damaged while the invasion path of moisture from the side face of the substrate is blocked will be described below with reference to the drawings.

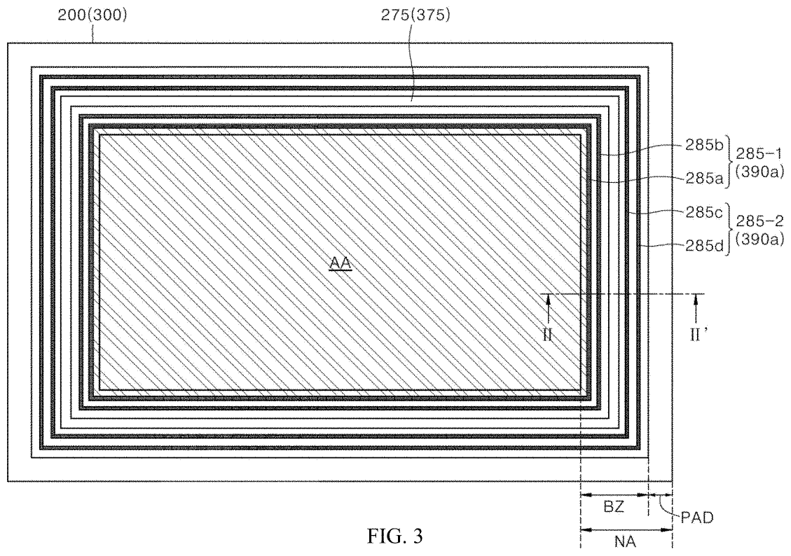

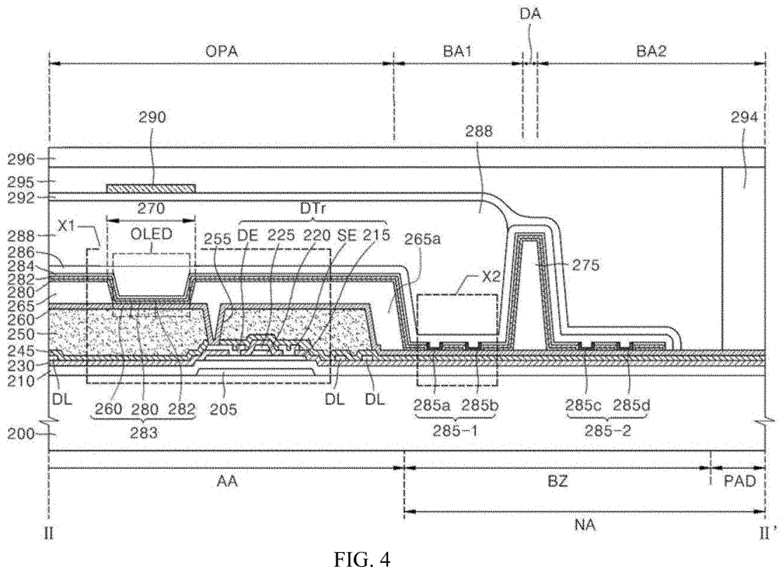

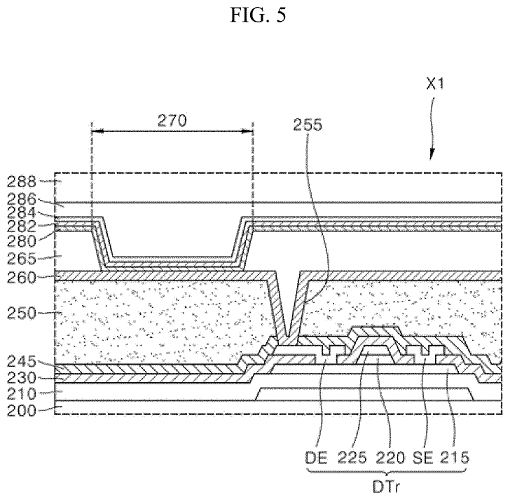

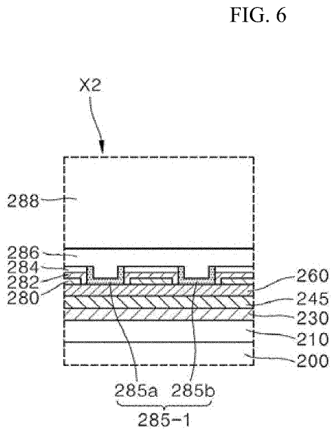

FIG. 3 is a plan view schematically shown to illustrate an organic light-emitting display device according to an aspect of the present disclosure. FIG. 4 is a cross-sectional view showing an II-II′ portion of FIG. 3. FIG. 5 and FIG. 6 are enlarged views showing portion “X1” and portion “X2” of FIG. 4, respectively. In this regard, FIG. 3 is a diagram selectively showing components for illustrating a dam pattern and a barrier pattern constituting the organic light-emitting display device.

Referring to FIG. 3 to FIG. 6, a substrate 200 of the organic light-emitting display device according to an aspect of the present disclosure includes a display area AA and a non-display area NA. The display area AA includes a plurality of pixels (P in FIG. 2). The non-display area NA surrounds the display area AA and may be configured to include a bezel area BZ and a pad area PAD. Further, a first barrier area BA1, a dam pattern area DA, and a second barrier area BA2 may be disposed in the non-display area NA.

A light-blocking layer 205, a buffer layer 210, a driving thin-film transistor DTr, an interlayer insulating film 230, a passivation film 245, a planarization layer 250, a bank 265, and an organic light-emitting element OLED may be disposed on the substrate 200 and in the display area AA.

The light-blocking layer 205 may be disposed on the substrate 200 so as to overlap the driving thin-film transistor DTr. The buffer layer 210 may be disposed on the light-blocking layer 205 and may be formed to cover the light-blocking layer 205. The buffer layer 210 may be composed of an inorganic insulating film, an organic insulating film, or a combination of an inorganic insulating film and an organic insulating film, and may have a single-layer or multi-layer structure.

The driving thin-film transistor DTr may be disposed on the buffer layer 210. In an aspect of the present disclosure, the driving transistor DTr may include an active area 215 disposed on the buffer layer 210, a gate insulating layer 220, a gate electrode 225, a source electrode SE, and a drain electrode DE. The source electrode SE and the drain electrode DE may be in direct contact with the active area 215, and may be spaced apart from each other while the gate electrode 225 is interposed therebetween.

The interlayer insulating film 230 may be disposed to cover all of the active area 215, the gate insulating layer 220, the gate electrode 225, the source electrode SE, and the drain electrode DE. The interlayer insulating film 230 may receive therein contact holes exposing a portion of a surface of the active area 215 such that the source electrode SE and the drain electrode DE contact the active area 215. In one example, the source electrode SE and the drain electrode DE may extend to cover a portion of a top surface of the interlayer insulating film 230 while filling the contact holes. However, the present disclosure is not limited thereto.

The plurality of data lines DL may be disposed on a top face of the interlayer insulating film 230. The passivation film 245 may be disposed on the plurality of data lines DL. The passivation film 245 serves to protect the components disposed thereunder, and may be composed of an inorganic insulating film or an organic insulating film.

The planarization layer 250 may be disposed on the passivation film 245. Another contact hole 255 may be defined in the planarization layer 250. Another contact hole 255 extending through the planarization layer 250 and the passivation film 245 exposes a portion of a surface of the drain electrode DE. The planarization layer 250 may be formed to have a sufficient thickness to planarize a surface in the display area AA and on the substrate 200.

In this regard, as the planarization layer 250 is not disposed in an area other than the display area AA, for example, the non-display area NA including the bezel area BZ and the pad area PAD, the surface of the interlayer insulating film 230 may be exposed.

The first electrode 260 is disposed on the planarization layer 250. The first electrode 260 may be electrically connected to the gate electrode 225 via the drain electrode DE exposed through another contact hole 255. In this regard, the first electrode 260 may be made of a transparent metal oxide such as Indium-Tin-Oxide (ITO) and Indium-Zinc-Oxide (IZO). The first electrode 260 may also be referred to as an anode electrode or a pixel electrode.

The first electrode 260 may be divided into portions which may be spaced apart from each other and may correspond to the plurality of pixels. In an aspect of the present disclosure, description about the outermost area OPA of the display area AA in which the outermost pixel 270 in is disposed is made. However, the disclosure is not limited thereto. For example, as shown in FIGS. 1 and 2, the plurality of pixels may be arranged in an entirety of the display area AA. Hereinafter, the outermost pixel may be referred to as to the pixel 270.

The first electrode 260 may extend along the outermost area OPA of the display area AA in which the outermost pixel 270 is disposed and may extend from the display area AA to and along the pad area PAD of the non-display area NA. When the first electrode 260 extends along the pad area PAD, the first electrode 260 may act as a metal layer constituting a plurality of pads disposed on the pad area PAD.

The bank 265 may be disposed on the planarization layer 250. The bank 265 may act as a boundary area defining a light-emitting area of the pixel 270, and serve to define each pixel. The bank 265 acts as a barrier to prevent light beams of different colors of adjacent pixels from being mixed with each other. The bank 265 may expose a portion of the first electrode 260 and cover the remaining portion thereof.

The bank 265 may divide the first electrode 260 into portions which may be spaced apart from each other and correspond to pixels. The bank 265 may fill the second contact hole 255 disposed in each pixel. A bank portion 265a of the bank 265 adjacent to the non-display area NA may extend to a boundary area between display area AA and the non-display area NA.

Each of the pixels 270 defined by the bank 265 may include an organic light-emitting element layer 283 including an organic light-emitting element OLED having a stack structure in which the first electrode 260, an organic light-emitting layer 280 and a second electrode 282 are stacked. A capping film 284 is disposed on the second electrode 282. The organic light-emitting layer 280 is in contact with the first electrode 260 formed on the substrate 200. In one example, the organic light-emitting layer 280 and the second electrode 282 may extend from the outermost area OPA where the outermost pixel is disposed to and along a portion of the bezel area BZ. For example, the organic light-emitting layer 280 and the second electrode 282 may extend along a first barrier area BA1, a dam pattern area DA, and a portion of a second barrier area BA2.

The organic light-emitting layer 280 may include a hole transport layer HTL, a light-emitting layer EML, an electron transport layer ETL, a hole blocking layer HBL, a hole injecting layer HIL, an electron blocking layer EBL and an electron injecting layer EIL.

A dam pattern 275 may be disposed on the substrate 200 and in the non-display area NA. The dam pattern 275 may be disposed in a dam pattern area DA located in the bezel area BZ of the non-display area NA. Specifically, the dam pattern 275 may be disposed at a location spaced apart by a predefined distance from an outer side face of the bank portion 265a disposed in the outermost area OPA.

Referring to FIG. 3, the dam pattern 275 may be formed to have a rectangular frame shape surrounding four sides of the substrate 200. In this regard, the dam pattern 275 is formed to have the same vertical dimension as that of the bank 265 or to have a vertical dimension such that a vertical level of a top face of the dam pattern is higher than that of a top face of the bank 265. In one example, the dam pattern 275 may be made of the same material as that of the bank 265. However, the present disclosure is not limited thereto.

The first barrier area BA1 and the second barrier area BA2 may be disposed in the non-display area NA of the substrate 200. A plurality of barrier patterns 285-1 and 285-2 are respectively disposed in the first barrier area BA1 and the second barrier area BA2 so as to prevent invasion of oxygen and moisture into the display area AA.

The first barrier area BA1 may be disposed between the bank portion 265a disposed in the outermost area OPA and the dam pattern 275 and may have a first width. Further, the second barrier area BA2 may be disposed between a distal end of the substrate 200 and the dam pattern 275, and may have a second width. In this regard, the distal end of the substrate 200 may be an outer side face located at the outermost edge of the display device.

As the first barrier area BA1 is disposed between the bank portion 265a disposed in the outermost area OPA and the dam pattern 275, the first barrier area BA1 may have a relatively smaller width than that of the second barrier area BA2. In another example, the first barrier area BA1 and the second barrier area BA2 may have the same width.

A plurality of first barrier patterns 285-1 are disposed in the first barrier area BA1. In addition, a plurality of second barrier patterns 285-2 are disposed in the second barrier area BA2. The first barrier pattern 285-1 and the second barrier pattern 285-2 may include at least two patterns 285a and 285b and at least two patterns 285c and 285d, respectively, to easily block the invasion path of moisture and oxygen.

In an aspect of the present disclosure, an example has been described in which the number of the patterns of the first barrier pattern 285-1 disposed in the first barrier area BA1 and the number of the patterns of the second barrier pattern 285-2 disposed in the second barrier area BA2 are equal to each other. However, the present disclosure is not limited thereto. In one example, the number of the patterns of the first barrier pattern 285-1 disposed in the first barrier area BA1 may be greater than the number of the patterns of the second barrier pattern 285-2 disposed in the second barrier area BA2. In another example, the number of the patterns of the second barrier pattern 285-2 disposed in the second barrier area BA2 may be greater than the number of the patterns of the first barrier pattern 285-1 disposed in the first barrier area BA1.

As shown in FIG. 3, the first barrier pattern 285-1 may have a frame shape surrounding four sides of the display area AA in a plan view. Further, as shown in FIG. 3, the second barrier pattern 285-2 may have a frame shape surrounding four outer sides of the dam pattern 275 in a plan view.

Further, a cross-sectional shape of each of the first barrier pattern 285-1 and the second barrier pattern 285-2 may have a ‘U’-shape such that each of the first barrier pattern 285-1 and the second barrier pattern 285-2 is composed of both opposing side walls and a bottom having a predefined thickness. In this regard, each of both opposing side walls and the bottom of each of the first barrier pattern 285-1 and the second barrier pattern 285-2 may have a thickness of several nm.

When the thickness of each of both opposing side walls and the bottom of each of the first barrier pattern 285-1 and the second barrier pattern 285-2 exceeds several nm and is several tens or hundreds of nm, the display device is defective. For this reason, each of both opposing side walls and the bottom of each of the first barrier pattern 285-1 and the second barrier pattern 285-2 may have a thickness of several nm, that is, may not exceed a critical value. Description thereof will be made in detail later. In one example, the thickness of each of both opposing side walls and the bottom of each of the first barrier pattern 285-1 and the second barrier pattern 285-2 may be in a range of 1 nm to 10 nm.

Each of the first barrier pattern 285-1 and the second barrier pattern 285-2 may be made of fluoropolymer in which carbon-carbon bonds are continuously arranged in a chain structure so as to have orthogonality, and a functional group contains a large amount of fluorine (F). The orthogonality may be understood as a property in which two objects are not related to each other but exist independently of each other. Accordingly, each of the first barrier pattern 285-1 and the second barrier pattern 285-2 may have both of a hydrophobic characteristic of having a low affinity with water and an oleophobic characteristic of having a low affinity with oil. Because of such orthogonality, each of the first barrier pattern 285-1 and the second barrier pattern 285-2 may be separated from or reject the moisture.

Each of the first barrier pattern 285-1 and the second barrier pattern 285-2 makes the emitting element layer 283 discontinuous in the bezel area BZ. In this regard, the emitting element layer 283 has a structure in which the first electrode 260, the organic light-emitting layer 280, the second electrode 282 and the capping film 284 are stacked. In this regard, the second electrode 282 may surround a face of each of discontinuous portions of the organic light-emitting layer 280 spaced from each other via each of the first barrier pattern 285-1 and the second barrier pattern 285-2 in each of the first barrier area BA1 and the second barrier area BA2.

Due to the orthogonality of each of the first barrier pattern 285-1 and the second barrier pattern 285-2, a stack structure in which the first electrode 260, the organic light-emitting layer 280, the second electrode 282, and the capping film 284 are stacked may be divided into the discontinuous portions spaced from each other via each of the plurality of first barrier patterns 285-1 and second barrier patterns 285-2 disposed in the bezel area BZ. Thus, the path through which moisture invades into the organic light-emitting layer 280 may be blocked. Specifically, due to the orthogonality of each of the first barrier pattern 285-1 and the second barrier pattern 285-2, each of the first barrier pattern 285-1 and the second barrier pattern 285-2 may be separated from or reject the moisture, and thus may block the invasion of moisture.

A vertical dimension of each of the first barrier pattern 285-1 and the second barrier pattern 285-2 may be sized such that each of the first barrier pattern 285-1 and the second barrier pattern 285-2 may cover at least an entirety of a sidewall of each of the second electrode 282 and the capping film 284. That is, the vertical dimension of each of the first barrier pattern 285-1 and the second barrier pattern 285-2 may be sized such that each of the first barrier pattern 285-1 and the second barrier pattern 285-2 may cover at least an entirety of a sidewall of the second electrode 282 surrounding a face of each of discontinuous portions of the organic light-emitting layer 280 spaced from each other via each of the first barrier pattern 285-1 and the second barrier pattern 285-2. In another example, the vertical dimension of each of the first barrier pattern 285-1 and the second barrier pattern 285-2 may be sized such that a top face of each of the first barrier pattern 285-1 and the second barrier pattern 285-2 has a higher vertical level than that of a top face of the capping film 284.

An encapsulation portion 286, 288, and 292 may be disposed on the capping film 284. The encapsulation portion 286, 288, and 292 may include a first encapsulation film 286, a cover film 288 and a second encapsulation film 292. The encapsulation portion 286, 288, and 292 may serve to prevent moisture, oxygen, or particles from invading from a front face of the substrate 200 into the organic light-emitting display device.

The first encapsulation film 286 and the second encapsulation film 292 may include an inorganic insulating film of the same type. However, the disclosure is not limited thereto. For example, each of the first and second encapsulation films 286 and 292 may include an inorganic insulating film made of, for example, silicon oxide (SiOₓ), silicon nitride (SiNₓ), aluminum oxide (AlOₓ), or aluminum nitride (AlNₓ).

The first encapsulation film 286 may fill an entirety of a recess of the ‘U’-shape of each of the first barrier pattern 285-1 and the second barrier pattern 285-2, and extends to and along the bezel area BZ in a conformal manner to the dam pattern 275.

The cover film 288 serves to prevent particles generated during the process or generated from the outside from moving into the device 100. The cover film 288 may be made of a transparent organic material, for example, epoxy resin, polyimide resin, or acryl resin. However, the disclosure is not limited thereto. The dam pattern 275 is disposed in the non-display area NA so as to prevent the cover film 288 from overflowing or spreading into the pad area PAD.

The second encapsulation film 292 may be disposed on the cover film 288, and may extend beyond the dam pattern 275 to and along the bezel area BZ. Accordingly, the second barrier pattern 285-2 disposed in the second barrier area BA2 may be covered with the first encapsulation film 286 and the second encapsulation film 292. Further, the first barrier pattern 285-1 disposed in the first barrier area BA1 may be covered with the first encapsulation film 286, the cover film 288, and the second encapsulation film 292.

A plurality of wavelength conversion patterns 290 may be disposed on the second encapsulation film 292. The wavelength conversion layer 290 converts a wavelength of light incident thereto from each pixel area 270. For example, when white light is incident thereto from the pixel area 270, the wavelength conversion pattern 290 may convert the white light into light of a color corresponding to each sub-pixel. Alternatively, the wavelength conversion pattern 290 may selectively transmit only a portion of light of a color corresponding to a sub-pixel therethrough.

A protective layer 295 is disposed on the wavelength conversion pattern 290 so as to cover the wavelength conversion pattern 290 and provide a planarized surface. The protective layer 295 covers the encapsulation portion 286, 288, and 292 in an area where the wavelength conversion pattern 290 is not disposed. In one example, the protective layer 295 may be made of an organic insulating material. The protective layer 295 may extend to and along the non-display area NA and may cover the bezel area BZ.

A side face sealing portion 294 may be further disposed in the non-display area NA and on the substrate 200. The side face sealing portion 294 may cover an entirety of the pad area PAD in one side edge of the substrate 200. Further, the side face sealing portion 294 may cover an entirety of an exposed side face of the protective layer 295. The side face sealing portion 294 may overlap the pad area PAD, and thus may serve to prevent reflection of external light from the first electrode 260 extending to and along the pad area PAD.

An optical film 296 may be disposed on the protective layer 295 and the side face sealing portion 294. The optical film 296 may have a form in which one or more functional layers are stacked. However, the present disclosure is not limited thereto. For example, the optical film 296 may include an anti-reflection layer such as a polarizing film (POL) that may prevent reflection of external light to improve outdoor visibility and contrast ratio of an image displayed on the display device. In another example, the optical film 296 may further include a barrier layer to prevent moisture or oxygen invasion from the front face of the substrate 200. In this case, the barrier layer may be made of a material with low moisture permeability, such as a polymer material.

In the organic light-emitting display device according to an aspect of the present disclosure, the first barrier area BA1 and the second barrier area BA2 may be disposed in the bezel area BZ. The plurality of first barrier patterns 285-1 and the plurality of second barrier patterns 285-2 may be disposed in the first barrier area BA1 and the second barrier area BA2, respectively. Thus, in the bezel area, the organic light-emitting layer may be divided into discontinuous portions which may be spaced from each other via each of the first barrier pattern 285-1 and the second barrier pattern 285-2. Accordingly, the moisture invasion path through which the moisture invades from the side face of the substrate 200 into the organic light-emitting layer 280 may be blocked. In particular, due to the orthogonality of the material constituting each of the first barrier pattern 285-1 and the second barrier pattern 285-2, each of the first barrier pattern 285-1 and the second barrier pattern 285-2 may be separated from moisture or may reject moisture, thereby blocking the invasion of moisture. This may prevent deterioration of the performance of the organic light-emitting element OLED, thereby securing reliability of a lifespan of the organic light-emitting display device.

Hereinafter, a method for manufacturing an organic light-emitting display device according to an aspect of the present disclosure will be described with reference to the drawings.

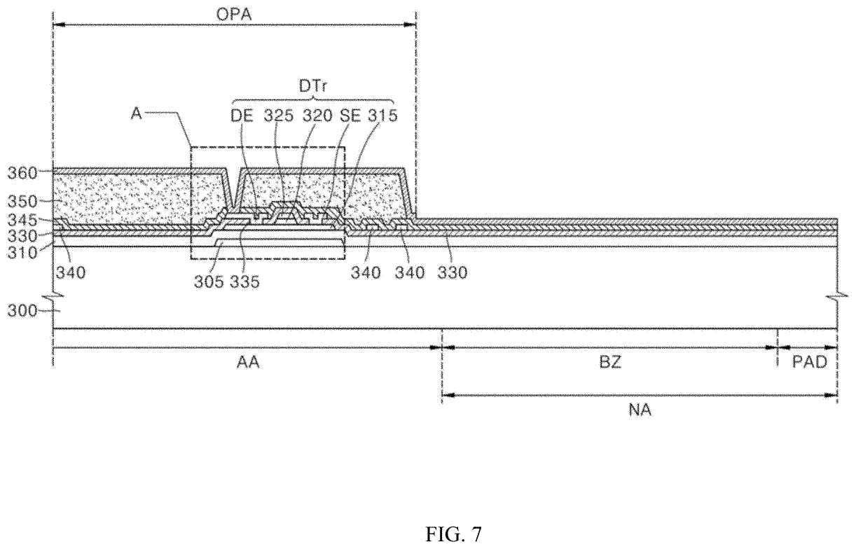

FIGS. 7 to 19 are diagrams for illustrating a method for manufacturing an organic light-emitting display device according to an aspect of the present disclosure. In this regard, FIGS. 7 to 19 are cross-sectional views taken along a line II-II′ in a plan view of FIG. 3.

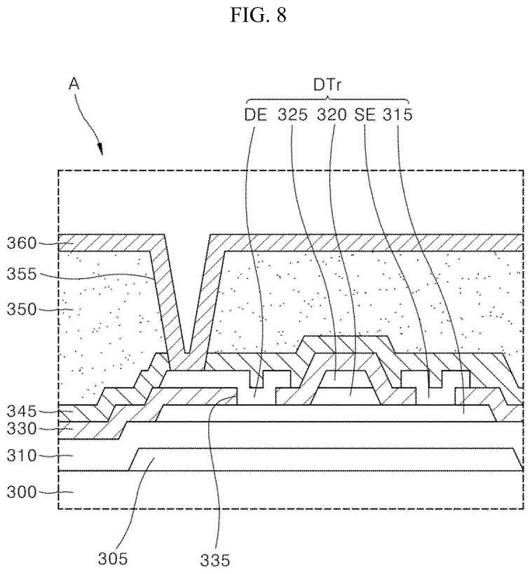

Referring to FIG. 7, and FIG. 8 as an enlarged view of an A portion of FIG. 7, a light-blocking layer 305 is formed on a substrate 300, and a buffer layer 310 covering an entire face of the substrate 300 is formed on the light-blocking layer 305. A driving transistor DTr may be disposed on the buffer layer 310.

The driving transistor DTr may include an active area 315 disposed on the buffer layer 310, a gate insulating layer 320 disposed on a channel area of the active area 315, a gate electrode 325 disposed on the gate insulating layer 320, a source electrode SE connected to a source area of the active area 315 and a drain electrode DE connected to a drain area of the active area 315.

The substrate 300 may be made of an insulating material. For example, the substrate 300 may be a light-transmissive substrate. The substrate 300 may be made of a hard material such as glass or tempered glass, or a flexible material made of plastic. However, the present disclosure is not limited thereto.

The light-blocking layer 305 may be disposed between the substrate 300 and the active area 315, and may be formed in a form of an isolated island. The light-blocking layer 305 may block the external light input to the driving transistor DTr to prevent an off-current from occurring in the driving transistor DTr due to change in a threshold voltage caused by the external light.

The buffer layer 310 may be made of an insulating material that may easily adhere to the active area 315. The buffer layer 310 not only helps to fix the active area 315, but also blocks the invasion of moisture or oxygen from the substrate 300 to the organic light-emitting element thereon, and may prevent hydrogen in the substrate 300 from moving upwardly of the substrate 300 during the process for manufacturing the driving transistor DTr.

In an example, the buffer layer 310 may be made of an inorganic insulating film including silicon oxide (SiOₓ), silicon nitride (SiNₓ), or silicon oxynitride (SiON), an organic insulating film, or a combination of an inorganic insulating film and an organic insulating film. The buffer layer 310 may be formed in a single layer or a multilayer structure including an inorganic insulating film and an organic insulating film.

The active area 315 includes a source area and a drain area including p-type or n-type impurity ions, and a channel area disposed between the source area and the drain area. The active area 315 may include at least one of amorphous silicon, polycrystalline silicon, and an oxide semiconductor.

The gate insulating layer 320 disposed on the active area 315 may be composed of a single layer made of an insulating material including silicon oxide (SiO) or silicon nitride (SiNₓ). However, the present disclosure is not limited thereto. For example, the gate insulating layer 320 may have a stack of layers made of silicon oxide (SiO) and silicon nitride (SiNₓ). The gate electrode 325 may be made of one selected from metals including chromium (Cr), molybdenum (Mo), aluminum (Al), gold (Au), titanium (Ti), nickel (Ni), copper (Cu), and the like, or alloys thereof.

An interlayer insulating film 330 is disposed on the gate electrode 325. The interlayer insulating film 330 may be formed on the gate electrode 325 and the active area 315 and over an entire face of the substrate 300 and may be formed to have a thickness sized such that the film 330 covers an entirety of a top face of the gate electrode 325. The interlayer insulating film 330 serves to electrically insulate the gate electrode 325 from the source electrode SE and the drain electrode DE from each other.

The interlayer insulating film 330 may be composed of a single layer made of an insulating material, for example, an inorganic insulating film or an organic insulating film, or may have a structure in which two or more insulating materials are stacked.

Examples of a material of the inorganic insulating film may include silicon oxide (SiOₓ) or silicon nitride (SiNₓ). Examples of a material of the organic insulating film may include acryl resin, epoxy resin, phenolic resin, polyamide resin, and polyimide resin. However, the present disclosure is not limited thereto.

First contact holes 335 exposing a portion of a surface of the active area 315 are defined in the interlayer insulating film 330. The first contact holes 335 may be filled with the source electrode SE and the drain electrode DE, respectively. The source electrode SE and the drain electrode DE may be spaced apart from each other while the gate electrode 325 is interposed therebetween. The source electrode SE and the drain electrode DE are electrically connected to the source area and the drain area via exposed portions of a surface of the active area 315, respectively. In one example, each of the source electrode SE and the drain electrode DE may extend to cover a portion of a top surface of the interlayer insulating film 330 while filling each of the first contact holes 335.

Each of the source electrode SE and the drain electrode DE may be made of one selected from metals including chromium (Cr), molybdenum (Mo), aluminum (Al), gold (Au), titanium (Ti), nickel (Ni), copper (Cu), and the like, or alloys thereof.

A plurality of data lines 340 may be disposed on the interlayer insulating film 330. The data line 340 serves to supply a data signal to each pixel area. Although not shown in the drawing, the data line 340 may be connected to one of a source electrode and a drain electrode of a switching thin-film transistor ST.

A passivation film 345 may be disposed on the interlayer insulating film 330. The passivation film 345 refers to an insulating film for protecting the components thereunder while covering the data line 340, and may be composed of a single layer made of an insulating material, for example, one of an inorganic insulating film and an organic insulating film, or may have a structure in which two or more insulating materials are stacked.

A planarization layer 350 having a second contact hole 355 defined therein may be disposed on the passivation film 345. As in the interlayer insulating film 330, the planarization layer 350 may be composed of a single layer made of an insulating material, for example, one of an inorganic insulating film and an organic insulating film, or may have a structure in which two or more insulating materials are stacked. The planarization layer 350 may be formed to have a sufficient thickness so as to realize a planarized surface while covering the display area AA of the substrate 300. In this regard, as the planarization layer 350 is not disposed in a remaining area except for the display area AA, for example, the non-display area NA including the bezel area BZ and the pad area PAD, the interlayer insulating film 330 is exposed.

The second contact hole 355 may extend through the planarization layer 350 and the passivation film 345, and may expose a portion of a surface of the drain electrode DE.

A first electrode 360 is formed on the planarization layer 350. The first electrode 360 may be electrically connected to the gate electrode 325 via the drain electrode DE exposed through the second contact hole 355. The first electrode 360 may be made of a transparent metal oxide such as Indium-Tin-Oxide (ITO) or Indium-Zinc-Oxide (IZO). The first electrode 360 may also be referred to as an anode electrode or a pixel electrode. Although not shown in the drawing, the first electrode 360 may be divided into portions which may be spaced apart from each other and may correspond to the plurality of pixels. The first electrode 360 may extend along the outermost area OPA of the display area AA in which the outermost pixel is disposed and may extend from the display area AA to and along the pad area PAD of the non-display area NA. When the first electrode 360 extends along the pad area PAD, the first electrode 360 may act as a metal layer constituting a plurality of pads disposed on the pad area PAD.

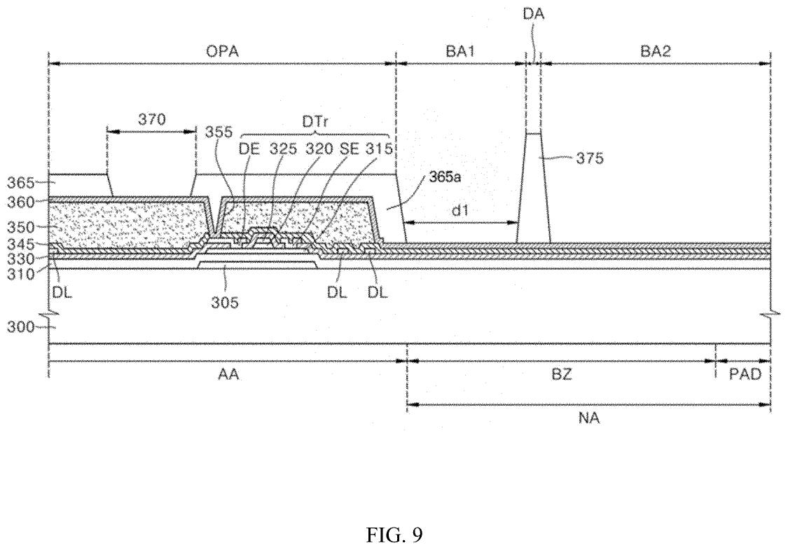

Referring to FIG. 9, a bank 365 is formed on the planarization layer 350. The bank 365 may expose a portion of the first electrode 360 and cover the remaining portion thereof. The bank 365 may act as a boundary area defining a light-emitting area of a pixel area 370, and serve to define each pixel. The bank 365 acts as a barrier to prevent light beams of different colors of adjacent pixels from being mixed with each other.

The bank 365 may divide the first electrode 360 into portions which may be spaced apart from each other and correspond to pixels. The bank 365 may fill the second contact hole 355 disposed in each pixel. A bank portion 365a of the bank 365 adjacent to the non-display area NA may extend to a boundary area between display area AA and the non-display area NA. For example, the bank portion 365a adjacent to the non-display area NA may be a bank portion 365a disposed in the outermost area OPA.

A dam pattern 375 may be disposed on the substrate 300 and in the non-display area NA. For example, the dam pattern 375 may be disposed on the first electrode 360 and in the bezel area BZ of the non-display area NA. The dam pattern 375 may be disposed at a position spaced apart by a first distance d1 from an outer side face of the bank portion 365a disposed in the outermost area OPA.

Referring to FIG. 3, the dam pattern 375 may be formed to have a rectangular frame shape surrounding four sides of the substrate 300. The dam pattern 375 serves to prevent the encapsulation portion to be subsequently formed from overflowing or spreading into the pad area PAD. In one example, the dam pattern 375 may be made of the same material as that of the bank 365. However, the present disclosure is not limited thereto. In this regard, the dam pattern 375 is formed to have the same vertical dimension as that of the bank 365 or to have a vertical dimension such that a vertical level of a top face of the dam pattern is higher than that of a top face of the bank 365.

The substrate 300 may further include the first barrier area BA1 and the second barrier area BA2 in the non-display area NA. The first barrier area BA1 may be disposed between the bank portion 365a disposed in the outermost area OPA and the dam pattern 375. Further, the second barrier area BA2 may be disposed between a distal end of the substrate 300 and the dam pattern 375. In this regard, the distal end of the substrate 300 may be an outer side face located at the outermost edge of the display device.

The first barrier area BA1 may have the first width extending from the dam pattern area DA in which the dam pattern 375 is disposed to the display area AA. The second barrier area BA2 may have the second width extending from the dam pattern area DA to the pad area PAD. As the first barrier area BA1 is disposed between the bank portion 365a disposed in the outermost area OPA and the dam pattern 375, the first barrier area BA1 may have a relatively smaller width than that of the second barrier area BA2. In another example, the first barrier area BA1 and the second barrier area BA2 may have the same width.

The first barrier area BA1 and the second barrier area BA2 may be areas where the first and second barrier patterns will be subsequently disposed, respectively. the first and second barrier patterns may serve to prevent invasion of oxygen and moisture to the display area AA where the organic light-emitting element is disposed.

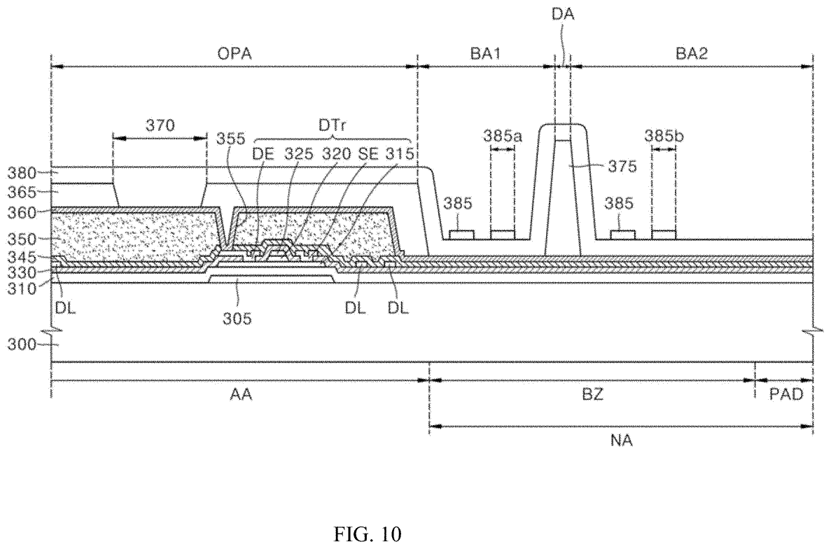

Referring to FIG. 10, a barrier layer 380 is formed on the entire face of the substrate 300. The barrier layer 380 prevents moisture invasion from the side face of the substrate 300, and thus serves to prevent the organic light-emitting element from being damaged due to the moisture permeation from the side face of the substrate, thereby preventing the performance of the display device from being degraded.

The barrier layer 380 may be made of fluoropolymer in which carbon-carbon bonds are continuously arranged in a chain structure (carbon-carbon backbone) so as to have orthogonality, and which contains a large amount of fluorine (F) at a functional group thereof.

A following [Chemical Formula 1] shows a chemical structural formula of a fluoropolymer material containing a large amount of fluorine (F) at a functional group, according to an example of the present disclosure.

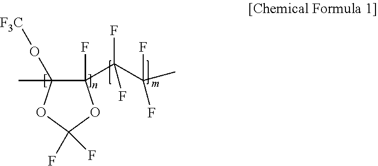

As shown in the above [Chemical Formula 1], the fluoropolymer used as a material for the barrier layer 380 according to the present disclosure contains a large amount of fluorine (F) at a functional group thereof. The fluoropolymer containing a large amount of fluorine (F) at a functional group has orthogonality. The orthogonality may be understood as a property in which two objects are not related to each other but exist independently of each other. Accordingly, the barrier layer 380 may have both of a hydrophobic characteristic of having a low affinity with water and an oleophobic characteristic of having a low affinity with oil. Under this orthogonality, the barrier layer 380 may be separated from moisture or reject the moisture. Accordingly, a path through which moisture permeates may be blocked by the barrier layer 380. Further, the barrier layer 380 may be less affected by a developer including an organic solvent used in a process step. Accordingly, damage to the barrier layer 380 caused by the organic solvent may be prevented.

The barrier layer 380 has a thickness sufficient to secure a vertical dimension sized such that the barrier pattern to be formed via selective removal of the barrier layer in a subsequent lift-off process acts as a moisture permeation prevention pattern.

After the barrier layer 380 has been formed, a mask pattern 385 is formed on the barrier layer 380. To this end, a mask film is formed on the barrier layer 380. The mask film may be formed by applying a photoresist material. Subsequently, an exposure process and a development process are performed on the mask film to form the mask pattern 385. The mask pattern 385 defines areas 385a and 385b in which the first and second barrier patterns are to be subsequently formed in the first barrier area BA1 and the second barrier area BA2, respectively. In one example, the mask pattern 385 may be formed to block the areas 385a and 385b where the barrier patterns are to be formed and to expose remaining areas. In this regard, a size (or width) of a portion of the mask pattern 385 formed in the first barrier area BA1 and a size (or width) of a portion of the mask pattern 385 formed in the second barrier area BA2 may be equal to each other or different from each other.

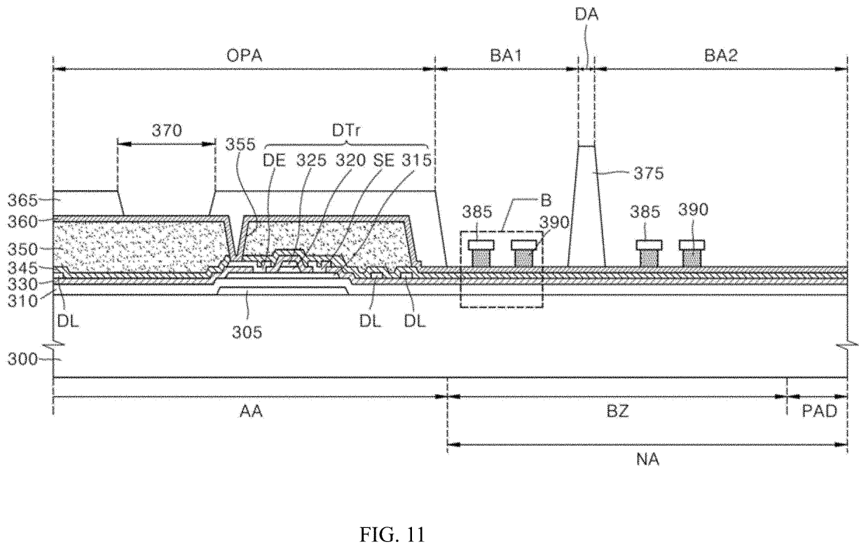

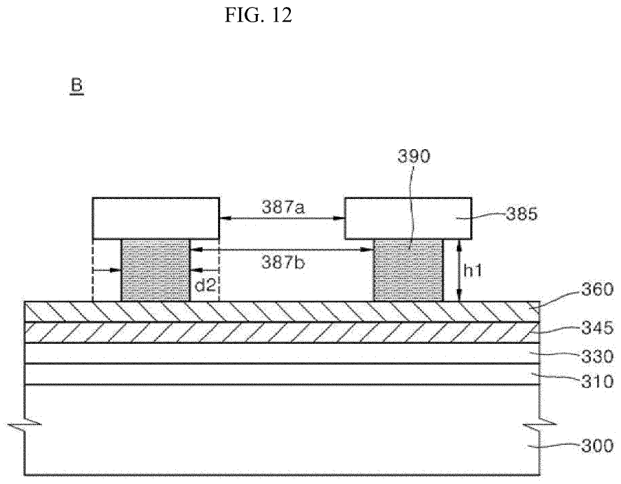

Referring to FIG. 11, and FIG. 12 as an enlarged view of a B portion of FIG. 11, an etching process is performed using the mask pattern 385 as an etching mask to form a preliminary barrier pattern 390. In one example, the etching process may be performed in a wet etching scheme. The preliminary barrier pattern 390 may be overetched into an undercut shape with respect to the mask pattern 385 under a wet etching process that is performed isotropically. The undercut refers to a phenomenon in which a portion under the mask pattern 385 is additionally etched.

In other words, while a side face of the preliminary barrier pattern 390 is aligned with a side face of the mask pattern 385, the preliminary barrier pattern 390 is not cut vertically, but is additionally etched horizontally inwardly of both opposing side faces thereof corresponding to both opposing side faces of the mask pattern 385 by a first depth d2. Accordingly, a second width 387b between the adjacent preliminary barrier patterns 390 is relatively larger than a first width 387a between the adjacent mask patterns 385. In this regard, the preliminary barrier pattern 390 may be formed to have the same thickness or vertical dimension) (a first vertical dimension h1) as that of the barrier layer 380.

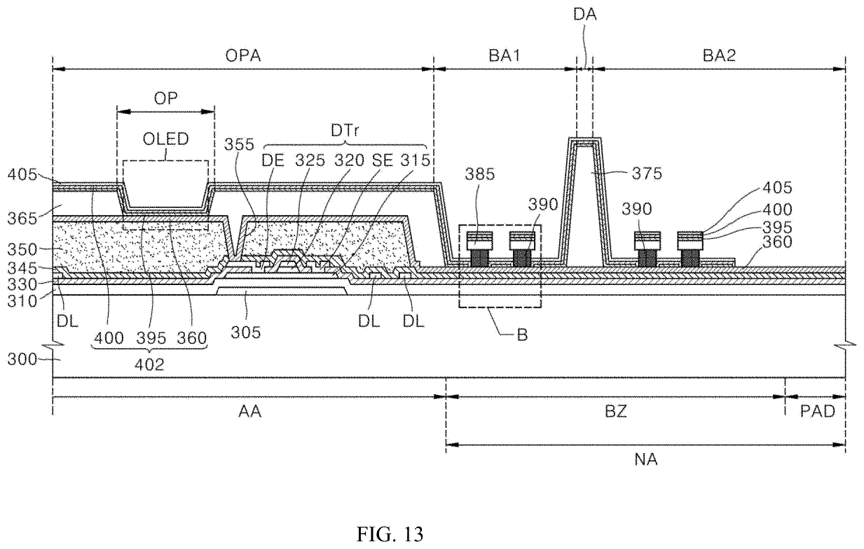

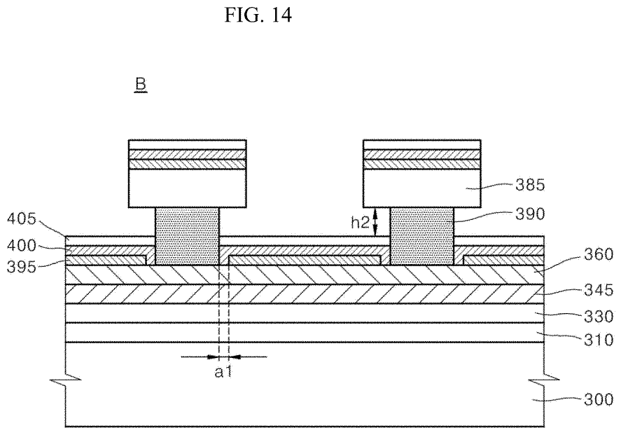

Referring to FIG. 13 and FIG. 14 as an enlarged view of a B portion of FIG. 13, an organic light-emitting layer 395 and a second electrode 400 are formed on the first electrode 360 to form an organic light-emitting element layer 402 including an organic light-emitting element OLED composed of the first electrode 360, the organic light-emitting layer 395 and the second electrode 400. Then, a capping film 405 is formed on the second electrode 400 as the uppermost layer of the organic light-emitting element layer 402.

The organic light-emitting layer 395 is connected to the first electrode 360 formed on the substrate 300. In an example, the organic light-emitting layer 395 may extend from the outermost area OPA in which the outermost pixel OP among pixels is disposed to and along the bezel area BZ. Accordingly, the organic light-emitting layer 395 may conformally cover an exposed face of the dam pattern 375 disposed in the dam pattern area DA of the non-display area NA.

The organic light-emitting layer 395 may also be formed between adjacent preliminary barrier patterns 390 disposed in the first barrier area BA1 and between adjacent preliminary barrier patterns 390 disposed in the second barrier area BA2. In this regard, since the mask pattern 385 is disposed on a top face of each of the preliminary barrier patterns 390, the organic light-emitting layer 395 is formed at a position spaced apart from a sidewall of the preliminary barrier pattern 390 by a first spacing al as shown in FIG. 14.

Although not shown in the drawing, the organic light-emitting layer 395 may include a stacked structure of a hole transport layer HTL, a light-emitting layer EML, and an electron transport layer ETL. Alternatively, the organic light-emitting layer 395 may be configured to include a hole transport layer HTL, a light-emitting layer EML, an electron transport layer ETL, a hole blocking layer HBL, a hole injecting layer HIL, an electron blocking layer EBL, and an electron injecting layer EIL.

Specifically, the hole transport layer HTL and the electron transport layer ETL of the organic light-emitting layer 395 play a role in balancing amounts of the electrons and the holes with each other. In this regard, the hole transport layer HTL serves to transport the holes supplied from the first electrode 360 to the light-emitting layer, while the electron transport layer ETL serves to transport the electrons supplied from the second electrode 400 to be subsequently formed to the light-emitting layer without loss thereof.

Further, the hole injection layer HIL and the electron injection layer EIL of the organic light-emitting layer 395 serve to facilitate the injection of electrons and holes, respectively. In this regard, the hole injection layer HIL may facilitate hole injection by lowering an injection energy barrier of the holes supplied from the first electrode 360. The electron injection layer EIL may facilitate electron injection by lowering a potential barrier during injection of electrons supplied from the second electrode 400. The hole blocking layer HBL plays a role in inhibiting movement of holes that are not combined with electrons in the light-emitting layer EML, while the electron blocking layer EBL plays a role in preventing electrons from moving from the light-emitting layer EML to the hole transport layer HTL. The light-emitting layer EML of the organic light-emitting layer 395 emits light via recombination of holes injected from the first electrode 360 and electrons injected from the second electrode 400.

The second electrode 400 may be connected to the organic light-emitting layer 395 and cover an entirety of an exposed face of the organic light-emitting layer 395. Accordingly, the second electrode 400 may extend to and along the bezel area BZ of the non-display area NA and cover the organic light-emitting layer 395 in a conformal manner to the dam pattern 375 disposed in the dam pattern area DA. The second electrode 400 may act as a common electrode which commonly contacts adjacent pixels including the outermost pixel OP in the display area AA and applies a voltage thereto. The second electrode 400 may be referred to as a cathode electrode.

In one example, the second electrode 400 may be made of a transparent metal oxide such as indium-tin-oxide (ITO) or indium-zinc-oxide (IZO). Alternatively, the second electrode 400 may be made of a semi-transmissive metal material such as molybdenum (Mo), tungsten (W), silver (Ag), or aluminum (Al) and an alloy including at least one thereof.

As the second electrode 400 extends to and along the bezel area BZ of the non-display area NA, the second electrode 400 may also be formed between adjacent preliminary barrier patterns 390 disposed in the first barrier area BA1 and between adjacent preliminary barrier patterns 390 disposed in the second barrier area BA2. In one example, the second electrode 400 is formed on the organic light-emitting layer 395 disposed in the first barrier area BA1 and the second barrier area BA2. Specifically, because the second electrode 400 has better step coverage compared to that of the organic light-emitting layer 395, the second electrode may fill a space between the preliminary barrier pattern 390 and a side face of the organic light-emitting layer 395 spaced apart from a sidewall of the preliminary barrier pattern 390 by the first spacing al. Accordingly, the second electrode 400 may be formed to cover an entirety of each of exposed side and top faces of the organic light-emitting layer 395.

The capping film 405 may be connected to the second electrode 400 so as to cover an entirety of an exposed face of the second electrode 400. Accordingly, the capping film 405 may extend to and along the bezel area BZ of the non-display area NA in which the second electrode 400 has been disposed. The capping film 405 may cover the second electrode 400 in a conformal manner to the dam pattern 375 disposed in the dam pattern area DA.

The capping film 405 reduces light loss that may occur under repeated reflection of light emitted from the light-emitting layer EML of the organic light-emitting layer 395 between the first electrode 360 and the second electrode 400, thereby increasing an amount of light directed toward the display area AA. The capping film 405 may include a material having a high refractive index. In one example, the capping film 405 may include an insulating film made of an organic material having a high refractive index. When the capping film 405 is formed, the preliminary barrier pattern 390 may protrude by a predefined vertical dimension h2 from a top face of the capping film 405 to expose portions of both opposing sidewalls of the preliminary barrier pattern 390.

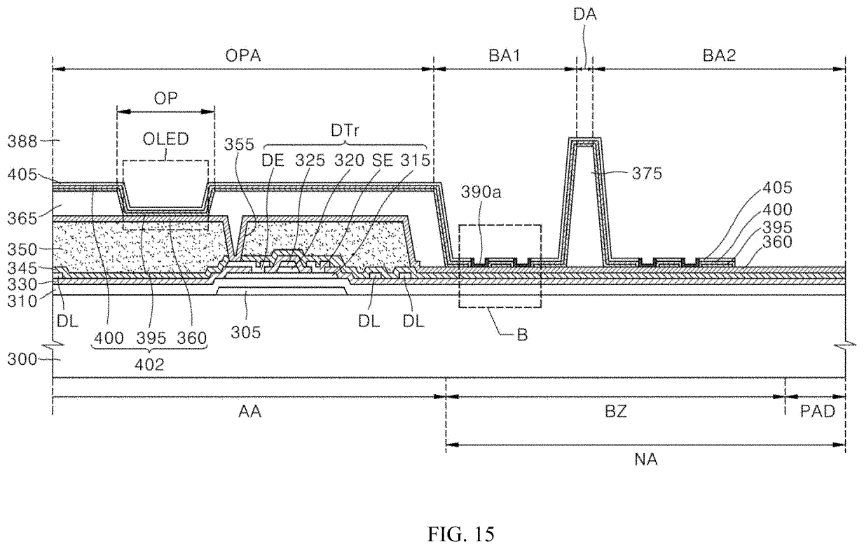

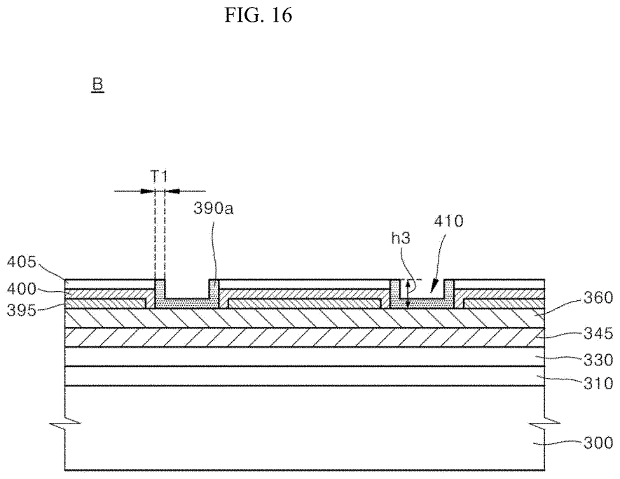

Referring to FIG. 15 and FIG. 16 as an enlarged view of a portion B of FIG. 15, a lift-off process is performed to form a plurality of barrier patterns 390a in the first barrier area BA1 and the second barrier area BA2.

The lift-off process may be performed using a fluorine (F)-based organic solvent. The fluorine (F)-based organic solvent may include a monomolecular or polymeric material in which carbon-carbon bonds are continuously arranged in a chain structure (carbon-carbon backbone), and which contains a large amount of fluorine (F) at a functional group thereof.

A following [Chemical Formula 2] shows a chemical structural formula of the fluorine (F)-based organic solvent according to an example.

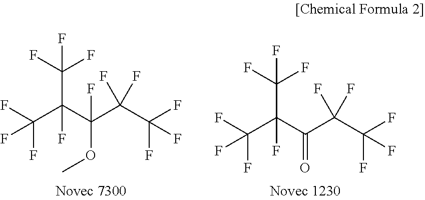

As shown in the above [Chemical Formula 2], the fluorine (F)-based organic solvent according to an example of the present disclosure contains a large amount of fluorine (F) at a functional group. The fluorine (F)-based organic solvent containing a large amount of fluorine (F) at the functional group may invade into and selectively remove the preliminary barrier pattern (390 in FIG. 12) which is made of the fluoropolymer material that contains a large amount of fluorine (F) at the functional group thereof. In this regard, the organic material that constitutes the organic light-emitting layer 395 is resistant to the fluorine (F)-based organic solvents, and thus may not deteriorate or change during the lift-off process. Thus, the organic material that constitutes the organic light-emitting layer 395 is not damaged during the lift-off process.

Each of the plurality of barrier patterns 390a formed in the first barrier area BA1 and the second barrier area BA2 may have a frame shape surrounding four sides of the substrate 300 as shown in FIG. 3 in a plan view. In this regard, some of the barrier patterns 390a may be disposed inwardly of the dam pattern 375 so as to surround the four sides of the display area AA, while the other thereof may be disposed outwardly of the dam pattern 375 and surround the four sides of the dam pattern 375.

Referring back to FIG. 13 and FIG. 14, the preliminary barrier pattern 390 protrudes by a predefined vertical dimension h2 from the top face of the capping film 405, so that portions of both opposing sidewalls of the preliminary barrier pattern 390 are exposed. Then, the fluorine (F) organic solvent invades into and removes the exposed portions of both opposing sidewalls of the preliminary barrier pattern 390.

In the process of performing the lift-off process, the exposed portions of both opposing sidewalls of the preliminary barrier pattern 390 are inwardly removed. Thus, the mask pattern 385 may be removed from the preliminary barrier pattern 390.

As shown in FIG. 16, the barrier pattern 390a formed via this lift-off process may cover an exposed face of a sidewall of each of the second electrode 400 and the capping film 405 and an exposed face of a top face of the first electrode 360. The sidewall of the barrier pattern 390a has a horizontal predefined thickness T1.

The barrier pattern 390a is composed of both opposing sidewalls and a bottom portion with a predefined thickness. Thus, a cross-sectional shape of the barrier pattern 390a has a ‘U’-shape having a valley 410. Further, referring to FIG. 3 as a plan view, the barrier pattern 390a may be formed to have a rectangular frame shape surrounding the four sides of the display area AA of the substrate 300 in a plan view.

The lift-off process proceeds to a time point when a thickness of each of both opposing sidewalls and the bottom portion of the barrier pattern 390a becomes several nm. In one example, a thickness of each of both opposing sidewalls and the bottom portion of the barrier pattern 390a may be in a range of 1 nm to 10 nm. At least one barrier pattern 390a may be disposed in the first barrier area BA1 between the bank portion 365a disposed in the outermost area OPA and the dam pattern 375. In one example, two or more barrier patterns 390a may be disposed to further improve the blocking effect of the moisture invasion path. Further, at least one barrier pattern 390a may be disposed in the second barrier area BA2 between the distal end of the substrate 300 and the dam pattern 375. In one example, two or more barrier patterns 390a may be disposed in the second barrier area BA2 to further improve the blocking effect of the moisture invasion path.

The barrier pattern 390a formed via the lift-off process is formed to have a vertical dimension (that is, a second vertical dimension h3) sized such that the barrier pattern covers an entirety of a sidewall of each of the second electrode 400 and the capping film 405. The barrier pattern 390a is formed to have a vertical dimension sized such that the barrier pattern covers at least an entirety of a sidewall of each of the second electrode 400 and the capping film 405 to prevent moisture invasion through the organic light-emitting layer 395.

In one example, the barrier pattern 390a may be formed to have the second vertical dimension (h3 in FIG. 16) smaller than an initial and first vertical dimension (h1 in FIG. 12) of the preliminary barrier pattern 390. In another example, the barrier pattern 390a may be formed to have a vertical dimension sized such that a top face thereof has a higher vertical level than that of a top face of the capping film 405.

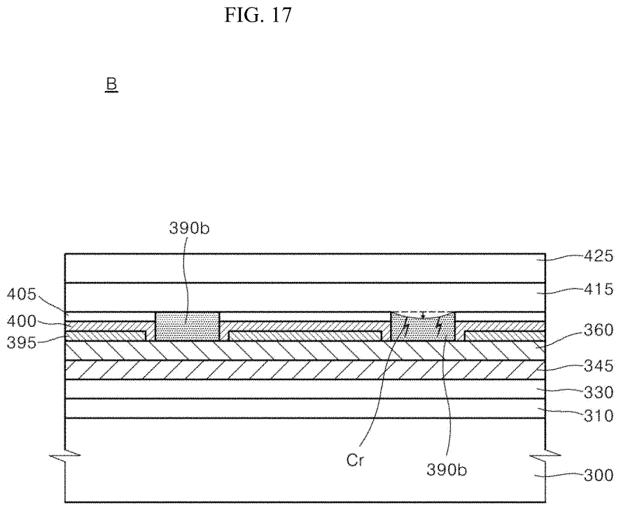

In one example, the barrier pattern 390a is composed of both opposing sidewalls and a bottom portion with a predefined thickness. Thus, a cross-sectional shape of the barrier pattern 390a has a ‘U’-shape having a valley 410. Further, the lift-off process proceeds to a time point when a thickness of each of both opposing sidewalls and the bottom portion of the barrier pattern 390a becomes several nm. In one example, a thickness of each of both opposing sidewalls and the bottom portion of the barrier pattern 390a may be in a range of 1 nm to 10 nm as a critical range. When the thickness of the barrier pattern 390a exceeds the critical range and thus is several tens or hundreds of nm, a defect may occur in the display device. Hereinafter, description will be made with reference to FIG. 17.

FIG. 17 is a diagram to illustrate a problem that occurs when the barrier pattern has a thickness exceeding the critical range.

Referring to FIG. 17, a barrier pattern 390b is formed to have a thickness sized such that the barrier pattern fills an entirety of a space between the adjacent organic light-emitting element layers 402. The thickness of this barrier pattern 390b exceeds the critical range. For example, the thickness is tens of nm or hundreds of nm. Thus, when encapsulation films 415 and 425 are formed on the barrier pattern 390b in a state in which the barrier pattern 390b is formed to have the thickness exceeding the critical range, a surface of the barrier pattern 390b may be depressed or the cracks inside the barrier pattern 390b may occur in a process of forming the first encapsulation film 415, as indicated by arrows in the drawing. When a subsequent process of forming the second encapsulation film 425 is performed in a state where such defects exist, arcing may occur in a portion adjacent to the pad area, resulting in defects in the display device.

Accordingly, in an aspect according to the present disclosure, the thickness of the barrier pattern 390a is within the critical range that is larger than 1 nm and does not exceed 10 nm. That is, the thickness of the barrier pattern 390a may be in a range of 1 nm to 10 nm.

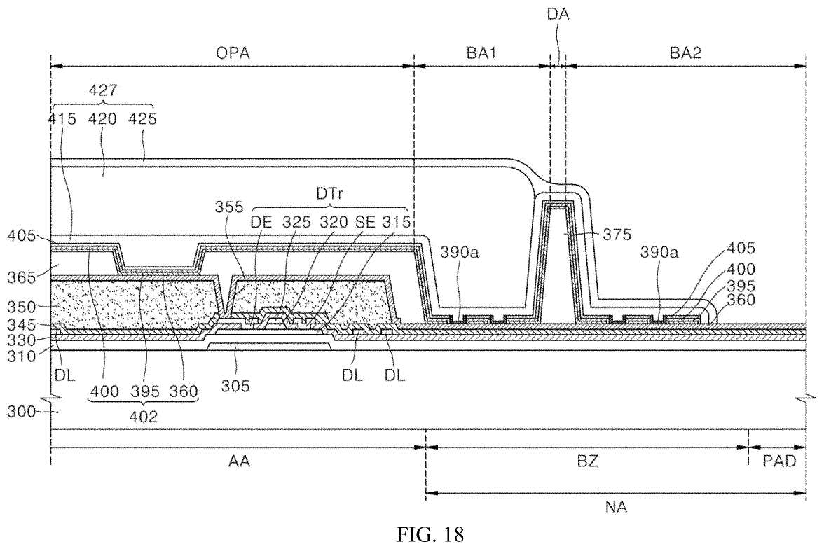

Referring to FIG. 18, an encapsulation portion 427 covering an entire face of the substrate 300 is formed. The encapsulation portion 427 may include a first encapsulation film 415, a cover film 420, and a second encapsulation film 425. The encapsulation portion 427 serves to prevent moisture, oxygen, or particles from entering the organic light-emitting display device.

The first encapsulation film 415 may include an inorganic insulating film. The first encapsulation film 415 may include an inorganic insulating film made of, for example, at least one among from materials having high insulating properties, such as silicon oxide (SiOₓ), silicon nitride (SiNₓ), aluminum oxide (AlOₓ), or aluminum nitride (AlNₓ).

The cover film 420 serves to prevent particles generated during the process or generated from the outside from moving into the device. The cover film 420 may be formed to have a thickness to sufficiently cover the particles to prevent the particles from entering the organic light-emitting element layer 402 and the second electrode 400 from the front face of the substrate 300. The cover film 420 may be made of a transparent organic material, for example, epoxy resin, polyimide resin, or acryl resin. However, the present disclosure is not limited thereto.

The second encapsulation film 425 may include the same inorganic insulating film as that of the first encapsulation film 415. In one example, the second encapsulation film 425 may include an inorganic insulating film made of, for example, at least one among from materials having high insulating properties, such as silicon oxide (SiOₓ), silicon nitride (SiNₓ), aluminum oxide (AlOₓ), or aluminum nitride (AlNₓ).

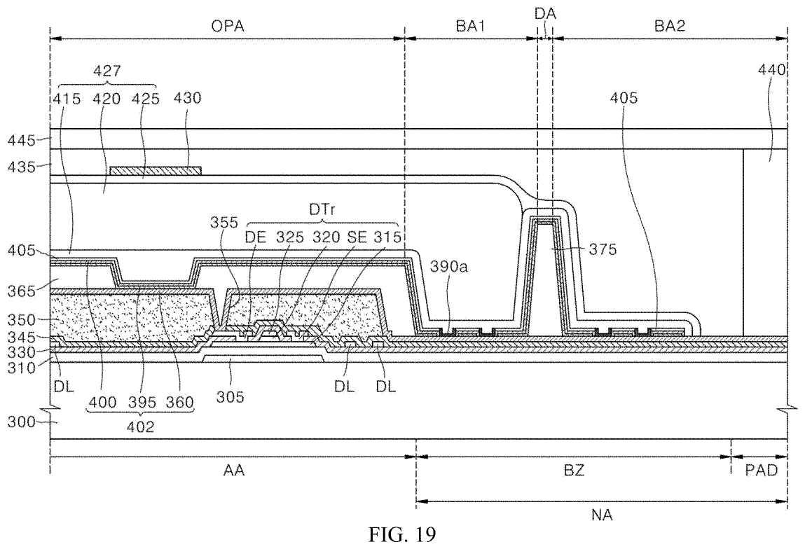

Referring to FIG. 19, a plurality of wavelength conversion patterns 430 disposed on the second encapsulation film 425 may be further included in the device. The wavelength conversion layer 430 converts a wavelength of light incident thereto from each pixel area. For example, when white light is incident thereto from the pixel area, the wavelength conversion pattern 430 may convert the white light into light of a color corresponding to each sub-pixel (SP in FIG. 2). Alternatively, the wavelength conversion pattern 430 may selectively transmit only a portion of light of a color corresponding to a sub-pixel therethrough. In one example, the plurality of wavelength conversion patterns 430 may correspond to a red light filter, a green light filter, and a blue light filter, respectively.

A protective layer 435 is disposed on the wavelength conversion pattern 430 so as to cover the wavelength conversion pattern 430 and provide a planarized surface. The protective layer 435 covers the encapsulation portion 427 in an area where the wavelength conversion pattern 430 is not disposed. The protective layer 435 may extend to and along the non-display area NA and may cover the bezel area BZ. In one example, the protective layer 435 may be made of an organic insulating material.

A side face sealing portion 440 may be further disposed in the non-display area NA and on the substrate 300. The side face sealing portion 440 may cover an entirety of the pad area PAD in one side edge of the substrate 300. Further, the side face sealing portion 440 may cover an entirety of an exposed side face of the protective layer 435. The side face sealing portion 440 may overlap the pad area PAD, and thus may serve to prevent reflection of external light from the first electrode 360 extending to and along the pad area PAD.

Further, the side face sealing portion 440 may play a role in preventing light from leaking out toward the side face of the substrate 300 due to a portion propagating from the wavelength conversion pattern 430 to an outside, of the light emitted from each sub-pixel.

An optical film 445 may be disposed on the protective layer 435 and the side face sealing portion 440. The optical film 445 may have a form in which one or more functional layers are stacked. However, the present disclosure is not limited thereto. For example, the optical film 445 may include an anti-reflection layer such as a polarizing film (POL) that may prevent reflection of external light to improve outdoor visibility and contrast ratio of an image displayed on the display device. In another example, the optical film 445 may further include a barrier layer to prevent moisture or oxygen invasion from the front face of the substrate 300. In this case, the barrier layer may be made of a material with low moisture permeability, such as a polymer material.

As described above, according to an aspect of the present disclosure, the barrier patterns 390a disposed in the bezel area BZ may block the invasion of moisture from the side face of the substrate 300 to prevent the performance degradation of the organic light-emitting element disposed inside the display device. For example, the organic light-emitting elements OLED of the organic light-emitting element layer 402 may be disposed not only in the pixel in an inner region of the display area AA but also in the outermost pixel OP in the outermost portion OPA of the edge portion of the display area. In particular, the organic light-emitting element OLED disposed in the outermost portion OPA of the display area AA deteriorates and the lifespan thereof is lowered when moisture invades thereto from the side face of the substrate 300, thereby reducing the reliability of the display device. To prevent this situation, the plurality of barrier patterns 390a to secure the reliability of the non-display area NA are arranged in the bezel area BZ such that the organic light-emitting element OLED is discontinuous in the bezel area, thereby blocking the path through which moisture may invade.

Accordingly, moisture invasion from the side face of the substrate 300 may be prevented so that no defects occur in each pixel. Thus, light of a color that the device wants to render may be generated in the display area. That is, the plurality of barrier pattern 390a may prevent the moisture invasion which causes degradation of the organic light-emitting element's performance. Thus, the lifespan of the organic light-emitting element may be further improved.

Further, when a scheme such as an undercut structure is introduced to prevent moisture invasion, the structure itself may be displaced and thus may act as foreign matter and defects. However, the barrier pattern according to an aspect of the present disclosure may prevent the foreign substances and defects from occurring. As described above, introducing the barrier pattern may allow the lifetime of the organic light-emitting element OLED to be secured, and allow the defects such as foreign substances to be prevented from occurring, thereby ensuring the reliability of the display device.

According to an aspect of the present disclosure, when one image is displayed on a large-screen display device implemented by arranging a plurality of display devices in a matrix manner, a width of a bezel is reduced to remove a seam that deteriorates the user's immersion in the image. In this case, the plurality of barrier patterns arranged in the bezel area BZ may block the moisture invasion path such that the reliability of the organic light-emitting display device may be secured.

Accordingly, the width of the bezel may be sufficiently reduced while preventing defects caused by the moisture invasion to the display device. Thus, in implementing the large-screen display device, a continuous image may be displayed even in a boundary area between adjacent ones of the plurality of display devices such that an immersion level of the viewer to the imager may be improved.

Further, according to the aspect of the present disclosure, the barrier pattern may be made of the fluoropolymer containing a large amount of fluorine at the functional group thereof. Thus, when the fluorine-based organic solvent is used, damage to the organic material constituting the light-emitting element may be prevented in the lift-off process.

Further, according to an aspect of the present disclosure, the thickness of the barrier pattern may be within the critical range, thereby preventing a surface of the barrier pattern from being depressed or occurrence of defects such as cracks inside the barrier pattern, thereby preventing occurrence of defects due to arcing phenomenon.

Although the aspects of the present disclosure have been described in more detail with reference to the accompanying drawings, the present disclosure is not necessarily limited to these aspects. The present disclosure may be implemented in various modified manners within the scope not departing from the technical idea of the present disclosure. Accordingly, the aspects disclosed in the present disclosure are not intended to limit the technical idea of the present disclosure, but to describe the present disclosure. the scope of the technical idea of the present disclosure is not limited by the aspects. Therefore, it should be understood that the aspects as described above are illustrative and non-limiting in all respects. The scope of protection of the present disclosure should be interpreted by the claims, and all technical ideas within the scope of the present disclosure should be interpreted as being included in the scope of the present disclosure.

What is claimed is:

1. An organic light-emitting display device comprising:
a substrate including a display area in which a plurality of pixels are disposed and a non-display area surrounding the display area;
a dam pattern surrounding the display area and positioned in the non-display area;
a first barrier pattern positioned in a first barrier area between the dam pattern and the display area;
a second barrier pattern positioned in a second barrier area outside the dam pattern;
an organic light-emitting element layer positioned in a pixel area, the first barrier area, and the second barrier area,
wherein the organic light-emitting element layer is divided into discontinuous portions spaced from each other via each of the first barrier pattern and the second barrier pattern and an encapsulation portion covering the display area, the organic light-emitting element layer, the first barrier pattern and the second barrier pattern.

2. The organic light-emitting device of claim 1, wherein the organic light-emitting element layer includes a first electrode, an organic light-emitting layer and a second electrode, and
wherein, in the non-display area, each of the organic light-emitting layer and the second electrode is divided into discontinuous portions spaced from each other via each of the first barrier pattern and the second barrier pattern.

3. The organic light-emitting device of claim 2, wherein the second electrode surrounds a face of each of the discontinuous portions of the organic light-emitting layer spaced from each other via each of the first barrier pattern and the second barrier pattern, and
wherein a vertical dimension of each of the both opposing sidewalls of each of the first barrier pattern and the second barrier pattern is equal to or larger than a vertical dimension of a sidewall of the second electrode surrounding the face of each of the discontinuous portions of the organic light-emitting layer.

4. The organic light-emitting device of claim 1, wherein the second barrier area is positioned between an outer side edge of the substrate and the dam pattern, and
wherein the first barrier area has a width smaller than a width of the second barrier area.

5. The organic light-emitting device of claim 1, wherein each of the first barrier pattern and the second barrier pattern includes a polymer material in which carbon-carbon bonds are continuously arranged in a chain structure so as to achieve orthogonality, and
wherein the polymer material contains a substantial amount of fluorine (F) at a functional group thereof.

6. The organic light-emitting device of claim 1, wherein the first barrier pattern has a frame shape surrounding four sides of the display area in a plan view of the device, and
wherein the second barrier pattern is positioned outside the dam pattern and has a frame shape surrounding four sides of the dam pattern in the plan view.

7. The organic light-emitting device of claim 1, wherein each of the first barrier pattern and the second barrier pattern includes a plurality of patterns.

8. The organic light-emitting device of claim 1, wherein each of the first barrier pattern and the second barrier pattern has both opposing sidewalls and a bottom portion such that a cross-sectional shape thereof is a ‘U’ shape having a valley.

9. A large-screen display device comprising:
a plurality of organic light-emitting display devices arranged along a first direction and a second direction intersecting the first direction so as to contact each other,
wherein each of the organic light-emitting display devices includes:
a substrate including a display area in which a plurality of pixels are disposed, and a non-display area surrounding the display area and having a bezel area;
a dam pattern surrounding the display area and positioned in the non-display area;
a first barrier pattern positioned in a first barrier area between the dam pattern and the display area;
a second barrier pattern positioned in a second barrier area outside the dam pattern;
an organic light-emitting element layer positioned in a pixel area, the first barrier area, and the second barrier area,
wherein the organic light-emitting element layer is divided into discontinuous portions spaced from each other via each of the first barrier pattern and the second barrier pattern, and an encapsulation portion covering the display area, the organic light-emitting element layer, the first barrier pattern and the second barrier pattern.

10. The large-screen display device of claim 9, wherein a width of a bezel area disposed between adjacent ones of the plurality of organic light-emitting display devices is smaller than a size of a pixel pitch between the adjacent ones.

11. The large-screen display device of claim 9, wherein the organic light-emitting element layer includes a first electrode, an organic light-emitting layer and a second electrode, and
Wherein, in the non-display area, each of the organic light-emitting layer and the second electrode is divided into discontinuous portions spaced from each other via each of the first barrier pattern and the second barrier pattern.

12. The large-screen display device of claim 11, wherein the second electrode surrounds a face of each of the discontinuous portions of the organic light-emitting layer spaced from each other via each of the first barrier pattern and the second barrier pattern.

13. The large-screen display device of claim 9, wherein each of the first barrier pattern and the second barrier pattern includes a polymer material in which carbon-carbon bonds are continuously arranged in a chain structure so as to achieve orthogonality, wherein the polymer material contains a substantial amount of fluorine (F) at a functional group thereof.

14. The large-screen display device of claim 9, wherein the first barrier pattern has a frame shape surrounding four sides of the display area in a plan view of the device, and
wherein the second barrier pattern is positioned outside the dam pattern and has a frame shape surrounding four sides of the dam pattern in the plan view.

15. The large-screen display device of claim 9, wherein each of the first barrier pattern and the second barrier pattern has both opposing sidewalls and a bottom portion such that a cross-sectional shape thereof is a ‘U’ shape having a valley.

16. The large-screen display device of claim 12, wherein a vertical dimension of each of the both opposing sidewalls of each of the first barrier pattern and the second barrier pattern is equal to or larger than a vertical dimension of a sidewall of the second electrode surrounding the face of each of the discontinuous portions of the organic light-emitting layer.

17. An organic light-emitting display device, comprising:
one or more barrier patterns disposed on a bezel area; and
an organic light-emitting element layer, wherein the organic light-emitting element layer is divided into discontinuous portions spaced from each other via the one or more barrier patterns.

18. The organic light-emitting display device of claim 17, wherein the barrier pattern includes a polymer material in which carbon-carbon bonds are continuously arranged in a chain structure so as to achieve orthogonality, and
wherein the polymer material contains a substantial amount of fluorine (F) at a functional group thereof.

19. The organic light-emitting display device of claim 17, wherein the barrier pattern has both opposing sidewalls and a bottom portion such that a cross-sectional shape thereof is a ‘U’ shape having a valley.

20. The organic light-emitting display device of claim 17, wherein the organic light-emitting element layer includes a first electrode, an organic light-emitting layer and a second electrode,
wherein each of the organic light-emitting layer and the second electrode is divided into discontinuous portions spaced from each other via the barrier pattern, wherein the second electrode surrounds a face of each of the discontinuous portions of the organic light-emitting layer spaced from each other via the barrier pattern, and
wherein the vertical dimension of each of the both opposing sidewalls of the barrier pattern is equal to or larger than a vertical dimension of a sidewall of the second electrode surrounding the face of each of the discontinuous portions of the organic light-emitting layer.
